(19) United States
(12) Patent Application Publication
(10) Pub. No.: US 2025/0022762 A1
(43) Pub. Date: Jan. 16, 2025

(54) SEMICONDUCTOR MODULE

(71) Applicant: FUJI ELECTRIC CO., LTD., Kawasaki-shi (JP)

(72) Inventor: Masayoshi NAKAZAWA, Matsumoto (JP)

(73) Assignee: FUJI ELECTRIC CO., LTD., Kawasaki-shi (JP)

(21) Appl. No.: 18/679,869

(22) Filed: May 31, 2024

(30) Foreign Application Priority Data
Jul. 13, 2023 (JP) 2023-115291

(51) Int. Cl. H01L 23/049; H01L 23/373; H01L 25/07

(52) U.S. Cl. CPC H01L 23/049; H01L 23/3735; H01L 25/072

(57) ABSTRACT

A semiconductor module includes: a heat radiation plate; a first insulating substrate disposed on a first surface of the heat radiation plate and having a semiconductor chip provided thereon; a frame-shaped case surrounding the first insulating substrate; external terminals provided across the inside and the outside of the case and electrically connected to the semiconductor chip via a bonding wire; and at least one second insulating substrate disposed between the heat radiation plate and the external terminals and having heat conductivity greater than that of the case. The second insulating substrate and the first surface of the heat radiation plate are bonded to each other by a heat conductive bonding material. Each external terminal and the second insulating substrate are joined to each other by press-fitting.

### CROSS REFERENCE TO RELATED APPLICATION

This Application claims priority from Japanese Patent Application No. 2023-115291, filed Jul. 13, 2023, the entire contents of which are incorporated herein by reference.

### BACKGROUND OF THE INVENTION

### Field of the Invention

The present disclosure relates to semiconductor modules.

### Description of Related Art

For example, as disclosed in Japanese Patent Application, Laid-Open Publication No. 2017-5129 and WO 2014/061211, a semiconductor module typified by a power semiconductor module generally includes an insulating substrate on which a semiconductor chip is provided, a case for accommodating therein the insulating substrate, and external terminals electrically connected to the semiconductor chip.

In Japanese Patent Application, Laid-Open Publication No. 2017-5129, a main terminal (an external terminal) to be fixed to a housing (a case) is electrically connected to a semiconductor chip or an insulating substrate via a bonding wire inside the casing. In Japanese Patent Application, Laid-Open Publication No. 2017-5129, the insulating substrate is arranged on a base plate made of a material having excellent heat conductivity such as copper or aluminum, and in order to reduce thermal resistance in a region between the main terminal and the base plate, a high heat dissipation insulator is arranged between the base plate and the main terminal. This high heat dissipation insulator is fixed along with the main terminal to the housing by insert molding.

In the module described in Japanese Patent Application, Laid-Open Publication No. 2017-5129, since the main terminal and the high heat dissipation insulator tend to be in a non-contact state at the time of assembly, thermal resistance between the main terminal and the base plate cannot be sufficiently reduced in some cases. Therefore, in the module described in Japanese Patent Application, Laid-Open Publication No. 2017-5129, the main terminal and the bonding wire may have excessive temperature rise.

### SUMMARY OF THE INVENTION

In consideration of the above circumstances, an object of the present disclosure is to suppress temperature rise of an external terminal and a bonding wire.

In order to solve the above problem, a semiconductor module according to an aspect of the present disclosure includes: a heat radiation plate; a first insulating substrate disposed on a first surface of the heat radiation plate and having a semiconductor chip provided thereon; a frame-shaped case surrounding the first insulating substrate; a plurality of external terminals provided across, inside and outside of the case, and electrically connected to the semiconductor chip via a bonding wire; and at least one second insulating substrate disposed between the heat radiation plate and the plurality of external terminals and having heat conductivity greater than that of the case, in which the at least one second insulating substrate and the first surface of the heat radiation plate are bonded to each other by a heat conductive bonding material, and each of the plurality of external terminals and the at least one second insulating substrate are joined to each other by press-fitting.

### BRIEF DESCRIPTION OF THE DRAWINGS

FIG. 1 is an exploded perspective view of a semiconductor module according to a first embodiment.

FIG. 2 is a sectional view of the semiconductor module according to the first embodiment.

FIG. 3 is a perspective view of an external terminal according to the first embodiment.

FIG. 4 is an explanatory diagram of joining between the external terminal and a second insulating substrate according to the first embodiment.

FIG. 5 is a bottom view of a case having external terminals fixed thereto.

FIG. 6 is an exploded perspective view of a semiconductor module according to a second embodiment.

FIG. 7 is a perspective view of an external terminal according to a first modification.

FIG. 8 is an explanatory diagram of joining between the external terminal and a second insulating substrate according to the first modification.

### DESCRIPTION OF THE EMBODIMENTS

Embodiments according to the present disclosure are explained below with reference to the attached drawings. The dimensions and scales of respective parts in the drawings may be different from those of actual products as appropriate and illustrative parts may be included in the drawings for ease of understanding. The scope of the present disclosure is not limited to these embodiments as long as there are descriptions particularly limiting the present disclosure in the following explanations.

### 1. First Embodiment

### 1-1. Overall Configuration of Semiconductor Module

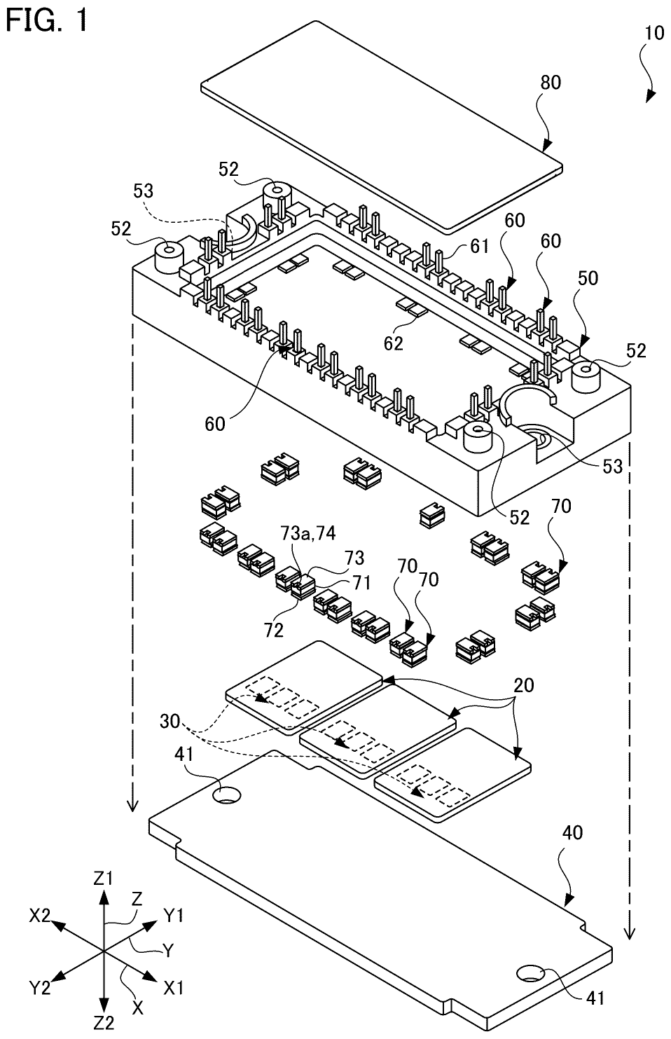

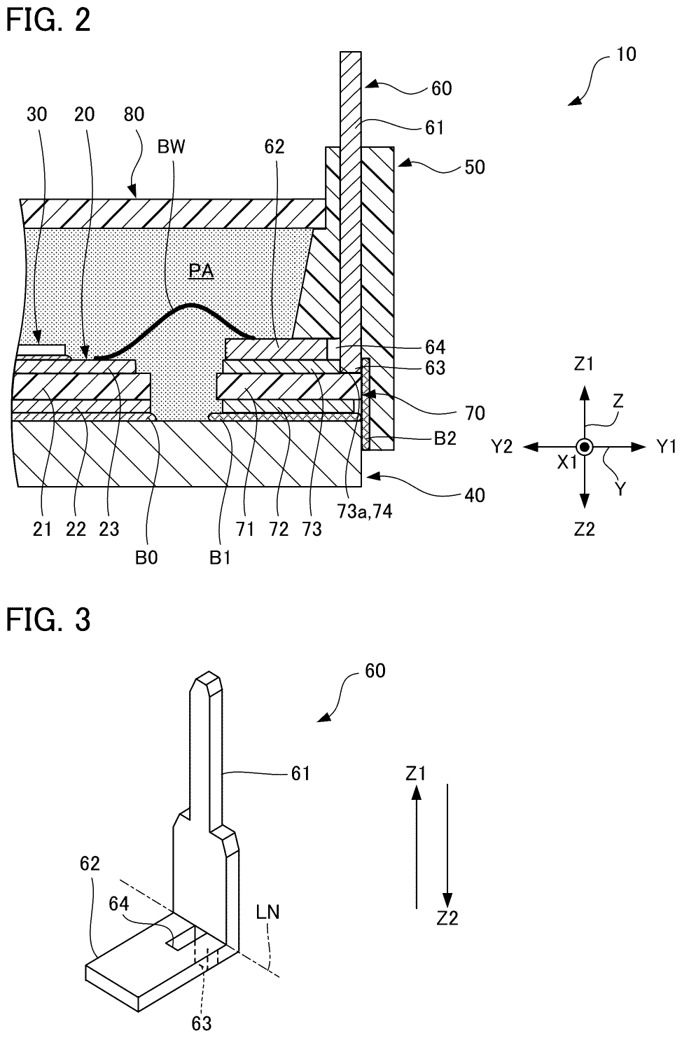

FIG. 1 is an exploded perspective view of a semiconductor module 10 according to a first embodiment. FIG. 2 is a sectional view of the semiconductor module 10 according to the first embodiment. FIG. 2 illustrates a cross section of a part of the semiconductor module 10 taken along a plane orthogonal to an X-axis.

The semiconductor module 10 is a power module, such as an IGBT (Insulated Gate Bipolar Transistor) module. For example, the semiconductor module 10 is used for power control included in an inverter or a rectifier to be incorporated in rail vehicles, automobiles, or home electrical machines.

As illustrated in FIG. 1, the semiconductor module 10 includes first insulating substrates 20, semiconductor chips 30, a heat radiation plate 40, a case 50, external terminals 60, second insulating substrates 70, and a cover 80. Although not illustrated in FIG. 1, as illustrated in FIG. 2, the semiconductor module 10 includes a potting agent PA in addition to the constituent elements described above. In FIG. 1, the semiconductor chips 30 are simply represented by alternating short dashed lines.

With reference to FIGS. 1 and 2, parts of the semiconductor module 10 are described hereinafter in order. In the following descriptions, for convenience, an X-axis, a Y-axis, and a Z-axis, orthogonal to one another, are used as appropriate. The Z-axis is parallel to a thickness direction of the semiconductor module 10. In the following descriptions, one direction along the X-axis is defined as an X1 direction, and the direction opposite to the X1 direction is defined an X2 direction. One direction along the Y-axis is defined a Y1 direction, and the direction opposite to the Y1 direction is defined as a Y2 direction. One direction along the Z-axis is defined as a Z1 direction, and the direction opposite to the Z1 direction is defined as a Z2 direction. Relationships between these directions and the vertical direction are not limited to any specific ones and are freely selectable. In the following descriptions, viewing in a direction along the Z-axis may be referred to as “plan view.”

Each of the first insulating substrates 20 is a substrate such as a DCB (Direct Copper Bonding) substrate or a DBA (Direct Bonded Aluminum) substrate. Although not illustrated in FIG. 1, as illustrated in FIG. 2, the first insulating substrate 20 includes an insulating plate 21, a conductor 22 disposed on a first surface of the insulating plate 21, and a conductor 23 disposed on a second surface of the insulating plate 21. The insulating plate 21 is insulating and is disposed so that its thickness direction coincides with a direction along the Z-axis. The insulating plate 21 is made of ceramic, such as aluminum nitride, aluminum oxide, or silicon nitride. The conductor 22 is planar and is disposed throughout substantially the entire region on a surface of the insulating plate 21 facing the Z2 direction. The conductor 23 is formed of flat conductors divided as appropriate and disposed on a surface of the insulating plate 21 facing the Z1 direction. Each of the conductor 22 and the conductor 23 is made of a metal, such as copper or aluminum.

The heat radiation plate 40 is bonded to the conductor 22 of each first insulating substrate 20 by a bonding material B0, such as solder. Semiconductor chips 30 are bonded to the conductor 23 of each first insulating substrate 20 by a bonding material, such as solder. In this manner, the first insulating substrate 20 is disposed on a first surface of the heat radiation plate 40, and the semiconductor chips 30 are provided on the first insulating substrate 20. The number of semiconductor chips 30 mounted to each first insulating substrate 20 is freely selectable. The number of first insulating substrates 20 included in the semiconductor module 10 is not limited to the number in the example illustrated in FIG. 1, and it may be two or less or four or more.

At least one of the semiconductor chips 30 mounted to the first insulating substrate 20 is a power semiconductor chip, such as an IGBT. On the first insulating substrate 20, as the semiconductor chips 30, in addition to a switching device (e.g., an IGBT), a control chip for controlling the power semiconductor chip may be mounted, and elements, such as an FWD (Freewheeling Diode) for commutating a load current may also be mounted.

The heat radiation plate 40 is a flat member for radiation to be disposed so that its thickness direction coincides with a direction along the Z-axis. The heat radiation plate 40 is made of, for example, copper, copper alloy, aluminum, or aluminum alloy. The heat radiation plate 40 has high heat conductivity and radiates heat from the semiconductor chips 30. The heat radiation plate 40 has high electrical conductivity as well and is electrically connected to a reference potential (e.g., a grounding potential). It is sufficient for the heat radiation plate 40 to have good heat conductivity; it is not limited to a metal plate and may be an insulator, such as a ceramic. A radiation member (e.g., a radiation fin) may be integrally provided on a surface of the heat radiation plate 40 facing the Z2 direction.

In the example illustrated in FIG. 1, as viewed in a direction along the Z-axis, the heat radiation plate 40 has a shape having a pair of long sides extending in a direction along the X-axis and a pair of short sides extending in a direction along the Y-axis. In the heat radiation plate 40, attachment holes 41 are provided near the respective short sides. The attachment holes 41 are through holes used to screw a radiation member, such as a radiation fin (not illustrated) to the heat radiation plate 40. The planar shape and the number of heat radiation plates 40 are not limited to those in the example illustrated in FIG. 1 and are freely selectable. The attachment holes 41 may be provided or omitted as necessary.

The case 50 is frame-shaped and accommodates therein the first insulating substrates 20 and the semiconductor chips 30. The case 50 is disposed so that its thickness direction coincides with a direction along the Z-axis and has a frame shape surrounding the first insulating substrates 20 in a plan view. The case 50 is substantially an insulator and is made of a resin material, such as PPS (polyphenylene sulfide) or PBT (polybutylene terephthalate). This resin material may contain an inorganic filler, such as alumina or silica from the viewpoint of improvement in the mechanical strength or reduction in the linear expansion coefficient of the case 50.

In the example illustrated in FIG. 1, as viewed in a direction along the Z-axis, the case 50 has a pair of long sides extending in a direction along the X-axis and a pair of short sides extending in a direction along the Y-axis. Two types of holes, holes 52 and holes 53, are provided in the case 50. The holes 52 are used to screw a substrate (not illustrated) having the semiconductor module 10 incorporated thereon in the case 50. The holes 53 are through holes used along with the attachment holes 41 to screw a radiation member, such as a radiation fin (not illustrated) to the heat radiation plate 40. The shape of the case 50 is not limited to the example illustrated in FIG. 1 and is freely selectable. The holes 52 and 53 may be omitted as appropriate.

The external terminals 60 are fixed to the case 50. The case 50 is formed by insert molding using each external terminal 60 that is an insert part. Since the external terminals 60 are firmly and stably fixed to the case 50, the external terminals 60 can be joined to the second insulating substrates 70 by press-fitting in a state in which the external terminals 60 are fixed to the case 50.

Each external terminal 60 is used to electrically connect the semiconductor chip 30 and a substrate (not illustrated) with the semiconductor module 10 to each other. As illustrated in FIG. 2, each external terminal 60 is provided across the inside and the outside of the case 50 and is electrically connected to the semiconductor chip 30 via a bonding wire BW. The external terminals 60 are made of metal, such as copper, copper alloy, aluminum, aluminum alloy, or iron alloy. For example, Sn or Sn—Cu may be plated on the surfaces of the external terminals 60.

The external terminals 60 of the semiconductor module 10 include two or more external terminals 60 through which a main current flows. The remaining external terminals 60 are control terminals for controlling operations of the semiconductor chips 30.

Each external terminal 60 is formed of a metal plate bent into substantially an L-shape. As illustrated in FIG. 2, the external terminal 60 has a pin portion 61, a leg portion 62, a projection 63, and a hole 64.

The pin portion 61 of each external terminal 60 is rod-shaped and extends in a direction along the Z-axis. An end of the pin portion 61 in the Z1 direction projects from an outer wall surface of the case 50. In this manner, the pin portion 61 has a terminal portion projecting from the outer wall surface of the case 50. This terminal portion is connected to a substrate (not illustrated) with the semiconductor module 10 incorporated thereon. On the other hand, the leg portion 62 is connected to an end of the pin portion 61 in the Z2 direction. The shape of the pin portion 61 is not limited to the example illustrated in FIG. 1 and may be a shape having a tip end of the pin portion 61 branched into two.

The leg portion 62 of each external terminal 60 is planar and is disposed on a surface of the second insulating substrate 70 facing the Z1 direction. The leg portion 62 extends from an end of the pin portion 61 in the Z2 direction toward the inside of the case 50. The leg portion 62 includes a portion between the case 50 and the second insulating substrate 70, and a pad portion exposed to the inside of the case 50. One end of the bonding wire BW illustrated in FIG. 2 is bonded to this pad portion. The other end of the bonding wire BW is connected to the first insulating substrate 20 or the semiconductor chip 30. With this connection, the external terminal 60 and the semiconductor chip 30 are electrically connected to each other.

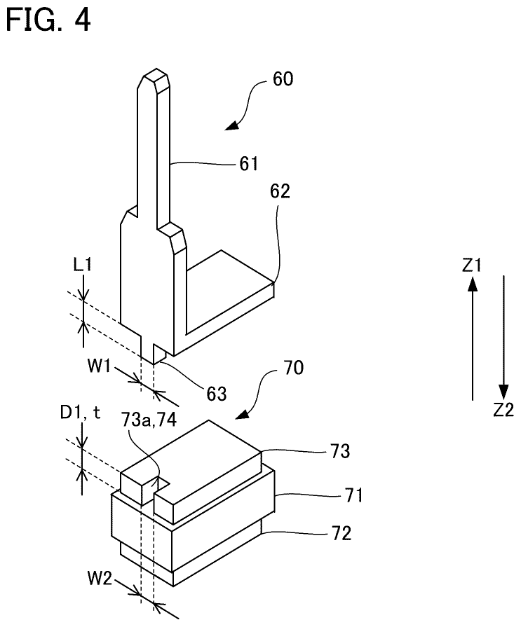

The projection 63 of each external terminal 60 projects from the leg portion 62 to the Z2 direction. The hole 64 is provided according to formation of the projection 63 when the external terminal 60 is formed by a bending process on a metal plate. Details of the projection 63 and the hole 64 are described later with reference to FIGS. 3 and 4.

The second insulating substrates 70 are arranged between the heat radiation plate 40 and the external terminals 60, and has heat conductivity greater than that of the case 50. The second insulating substrates 70 are arranged so that its thickness direction coincides with a direction along the Z-axis. In the present embodiment, the second insulating substrates 70 are separated for each of the external terminals 60. The second insulating substrates 70 correspond to the external terminals 60, respectively. As a result, a corresponding second insulating substrate 70 is interposed between the heat radiation plate 40 and each of the external terminals 60. In addition to the second insulating substrates 70 corresponding to the external terminals 60, it is permissible to provide another second insulating substrate 70 interposed between the heat radiation plate 40 and the case 50 without contributing to joining to the external terminals 60.

Each second insulating substrate 70 has the same layer structure as that of the first insulating substrate 20. That is, each second insulating substrate 70 is, for example, a DCB (Direct Copper Bonding) substrate or a DBA (Direct Bonded Aluminum) substrate. As a result, as compared with a configuration in which the layer structures of the first insulating substrate 20 and the second insulating substrate 70 are different from each other, the semiconductor module 10 is manufactured at a lower cost.

Specifically, as illustrated in FIGS. 1 and 2, the second insulating substrate 70 includes an insulating plate 71, a first conductor 72 disposed on a first surface of the insulating plate 71, and a second conductor 73 disposed on a second surface of the insulating plate 71. The insulating plate 71 is disposed so that its thickness direction coincides with a direction along the Z-axis. For example, the insulating plate 71 is made of ceramic, such as aluminum nitride, aluminum oxide, or silicon nitride. The first conductor 72 is planar and is disposed throughout the substantially entire region on a surface of the insulating plate 71 facing the Z2 direction. The first conductor 72 is bonded to the first surface of the heat radiation plate 40 by a bonding material B1. The second conductor 73 is planar and is disposed substantially throughout the entire region on a surface of the insulating plate 71 facing the Z1 direction. The second conductors 73 are separated for each external terminal 60. A notch 73a is provided in the second conductor 73. Each of the first conductor 72 and the second conductor 73 is made of metal, such as copper or aluminum.

The notch 73a constitutes a recess portion 74 to which the projection 63 is press-fitted. As a result, each of the external terminals 60 and each of the second insulating substrates 70 are joined to each other by press-fitting. Details of the recess portion 74 are described later with reference to FIGS. 3 and 4.

The surface of each second insulating substrate 70 facing the Z2 direction is bonded by the bonding material B1 to the surface of the heat radiation plate 40 facing the Z1 direction. The bonding material B1 is solder, for example. The solder is not limited to any specific type. Examples of the solder include lead-free solder such as SnAg-based, SnAgCu-based, SnBi-based, SnZnBi-based, SnCu-based, SnAgBi-based, SnSb-based, and SnAnAl-based solder. In this manner, the second insulating substrates 70 and the first surface of the heat radiation plate 40 are bonded to each other by the heat-conductive bonding material B1. The bonding material B1 is not limited to solder, and it may be an adhesive agent. Examples of the adhesive agent include an epoxy-based adhesive agent, an acryl-based adhesive agent, a urethane-based adhesive agent, and a silicone-based adhesive agent, each containing an inorganic filler (e.g., silica and alumina).

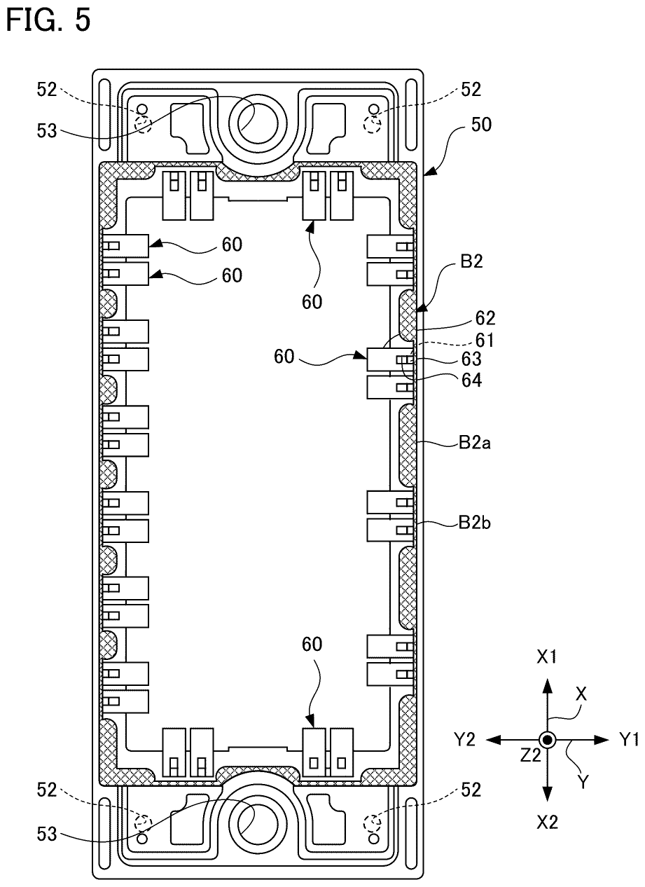

The heat radiation plate 40 and the case 50 are bonded to each other by an adhesive agent B2. The adhesive agent B2 is insulative. Examples of the adhesive agent B2 include an epoxy-based adhesive agent, an acryl-based adhesive agent, a urethane-based adhesive agent, and a silicone-based adhesive agent. The adhesive agent B2 may contain an inorganic filler, such as alumina or silica. Arrangement of the adhesive agent B2 is described later with reference to FIG. 5.

The cover 80 is planar and is bonded to a surface of the case 50 facing the Z1 direction. In substantially the same manner as the case 50, the cover 80 is made of a resin material, such as PPS (polyphenylene sulfide) or PBT (polybutylene terephthalate). The cover 80 is bonded to the case 50 by an adhesive agent so as to seal the gap between the cover 80 and the case 50.

As illustrated in FIG. 2, the physical space surrounded by the heat radiation plate 40, the case 50, and the cover 80 is filled with the potting agent PA that covers the semiconductor chips 30. The potting agent PA is made of, for example, silicone resin, such as silicone gel.

In the forementioned semiconductor module 10, each of the external terminals 60 is connected to the heat radiation plate 40 via the second insulating substrate 70 having heat conductivity greater than that of the case 50. As a result, Joule heat generated at the bonding wire BW and the external terminal 60 is released to the heat radiation plate 40 through the second insulating substrate 70. The second insulating substrate 70 and the heat radiation plate 40 are bonded to each other by the high heat conductive bonding material B1. As a result, thermal resistance between the second insulating substrate 70 and the heat radiation plate 40 is reduced. In addition, the external terminal 60 and the second insulating substrate 70 are joined to each other by press-fitting. As a result, thermal resistance between the external terminal 60 and the second insulating substrate 70 is reduced and assembly of the external terminal 60 and the second insulating substrate 70 is facilitated. Therefore, temperature increase of the external terminal 60 and the bonding wire BW is suppressed.

### 1-2. External Terminal and Second Insulating substrate

FIG. 3 is a perspective view of the external terminal 60 according to the first embodiment. FIG. 4 is an explanatory diagram of joining between the external terminal 60 and the second insulating substrate 70 according to the first embodiment. As illustrated in FIGS. 3 and 4, the external terminal 60 has a shape bent along a straight line LN along the boundary between the pin portion 61 and the leg portion 62, and is integrally formed by a bending process on a metal plate.

In this manner, by forming each external terminal 60 by a bending process on a metal plate, the semiconductor module 10 can be manufactured at a cost lower than that in an aspect in which the external terminal 60 is manufactured by using welding or the like.

The projection 63 projects from the leg portion 62 to the Z2 direction. In the examples illustrated in FIGS. 3 and 4, the projection 63 is disposed along the same plane as the pin portion 61. In the leg portion 62, the hole 64 is formed corresponding to the projection 63 at the time of a bending process on a metal plate.

In this manner, each external terminal 60 has the projection 63 projecting toward the second insulating substrate 70.

The recess portion 74 of the second insulating substrate 70 is a concave open toward the Z1 direction. In the example illustrated in FIG. 4, the recess portion 74 is formed by the notch 73a provided in the second conductor 73. The recess portion 74 includes a wall surface defined by the notch 73a, and a bottom surface that is a surface of the insulating plate 71 facing the Z1 direction.

Thus, each second insulating substrate 70 has the recess portion 74 that will be press-fitted to the projection 63. This configuration provides an advantage in that the contact area between the external terminal 60 and the second insulating substrate 70 can be easily increased. This is because the hole 64 can be easily made smaller than a notch 66 of a first modification (described later), in contrast to when the recess portion 74 provided in the external terminal 60 and a projection portion provided on the second insulating substrate 70 are joined by press-fitting.

By forming the recess portion 74 using a notch opened through the second conductor 73, the external terminal 60 and the second insulating substrate 70 can be easily joined to each other by press-fitting. The second conductor 73 may have a hole opened through the second conductor 73. In this case, the recess portion 74 may be formed by this hole in place of the notch 73a.

As described above, the layer structure of the second insulating substrate 70 is the same as that of the first insulating substrate 20. Specifically, the insulating plate 71 of the second insulating substrate 70 is made of the same material and having the same thicknesses as those of the insulating plate 21 of the first insulating substrate 20. The first conductor 72 of the second insulating substrate 70 is made of the same material and with the same thickness as those of the conductor 22 of the first insulating substrate 20. The second conductor 73 of the second insulating substrate 70 is made of the same material and having the same thicknesses as those of the conductor 23 of the first insulating substrate 20.

The projection 63 is press-fitted to the recess portion 74, thereby joining the external terminal 60 and the second insulating substrate 70 to each other.

Since the second conductors 73 are separated for each of the external terminals 60, the external terminals 60 can be joined to the second conductors 73 by press-fitting, and conduction between the external terminals 60 is prevented. Furthermore, two or more second insulating substrates 70 are provided. As a result, as compared with an aspect in which one second insulating substrate 70 is provided, thermal stress between the second insulating substrates 70 and the case 50 is reduced.

The second insulating substrates 70 are separated for each external terminal 60. For this reason, the second insulating substrates 70 can be shared among semiconductor modules 10 mutually differing from each other in arrangement of the external terminals 60. The semiconductor module 10 can be manufactured at a lower cost.

Each external terminal 60 has the projection 63, which projects toward at least one second insulating substrate 70. At least one second insulating substrate 70 has the recess portion 74 that fits the projection 63 by press-fitting. This configuration provides an advantage in that the contact area between the external terminal 60 and the second insulating substrate 70 is more easily increased, as compared with an aspect in which the recess portion 74 provided in the external terminal 60 and the projection portion provided on the second insulating substrate 70 are joined by press-fitting.

The recess portion 74 has a width W2 greater than a width W1 of the projection 63 so that the projection 63 has a fastening margin that enables the projection 63 to be press-fitted to the recess portion 74. This fastening margin is approximately 0.04 mm or more and 0.18 mm or less. The width W1 is a maximum width of the projection 63. On the other hand, the width W2 is a minimum width of the recess portion 74. In the examples illustrated in FIGS. 3 and 4, the projection 63 and the recess portion 74 each have a constant width. However, the projection 63 may not have a constant width. For example, the projection 63 may have a tapered surface so that the width of the projection 63 decreases to the Z2 direction. Alternatively, the recess portion 74 may not have a constant width. For example, the recess portion 74 may have a tapered surface so that the width of the recess portion 74 increases to the Z1 direction.

A projecting length L1 of the projection 63 is equal to or less than a depth D1 of the recess portion 74, that is, a thickness t of the second conductor 73. For this reason, forming the recess portion 74 in the insulating plate 71 is unnecessary, thereby enabling the second insulating substrate 70 to be manufactured easily. Furthermore, the projection 63 can be press-fitted into the recess portion 74 up to its root. As a result, two surfaces, the surface of the leg portion 62 facing the Z2 direction and the surface of the second conductor 73 facing the Z1 direction, are in contact with each other over a wide area. With this configuration, the contact area between the external terminal 60 and the second insulating substrate 70 is increased, thereby enabling thermal resistance between the external terminal 60 and the second insulating substrate 70 to be reduced.

A gap may be between the external terminal 60 and the second insulating substrate 70. In this case, in this gap, it is preferable to interpose a heat conductive material, such as an adhesive agent or grease that has excellent heat conductivity.

The surface of the second insulating substrate 70 facing the Z2 direction is bonded to the surface of the heat radiation plate 40 facing the Z1 direction by the bonding material B1 with excellent heat conductivity. The bonding material B1 is solder, for example. Accordingly, the heat radiation plate 40 and the second insulating substrates 70 are firmly bonded by the bonding material B1, and thermal resistance between the heat radiation plate 40 and the second insulating substrates 70 is reduced.

The solder is not limited thereto. Examples of the solder include lead-free solder, such as SnAg-based, SnAgCu-based, SnBi-based, SnZnBi-based, SnCu-based, SnAgBi-based, SnSb-based, and SnAnAl-based solder. The bonding material B1 is not limited to solder, and it may be an adhesive agent, such as an epoxy-based adhesive agent, an acryl-based adhesive agent, a urethane-based adhesive agent, or a silicone-based adhesive agent containing an inorganic filler such as silica or alumina.

The heat radiation plate 40 and the case 50 are bonded to each other by the adhesive agent B2.

FIG. 5 is a bottom view of the case 50 having the external terminals 60 fixed thereto. In FIG. 5, the case 50 as viewed in the Z1 direction is illustrated along with the external terminals 60.

As illustrated in FIG. 5, on the bottom surface of the case 50, that is, on the surface of the case 50 facing the Z2 direction, the leg portions 62 of the external terminals 60 are arranged.

The adhesive agent B2 is provided throughout the entire region of the outer circumference of the heat radiation plate 40. The adhesive agent B2 is disposed so as to circumvent the leg portions 62 of the external terminals 60, and includes parts B2a and parts B2b. The parts B2a are portions of the adhesive agent B2 to bond the surface of the heat radiation plate 40 facing the Z1 direction and the case 50, and are arranged so as to circumvent the leg portions 62 of the external terminals 60. The parts B2b are portions of the adhesive agent B2 to bond a side surface of the heat radiation plate 40 and the case 50, and are arranged throughout the entire circumference of the side surface of the heat radiation plate 40.

In this manner, the case 50 and the heat radiation plate 40 are bonded to each other by the adhesive agent B2. As a result, insulation between the external terminals 60 and the heat radiation plate 40 is secured. In addition, the gap between the case 50 and the heat radiation plate 40 is sealed by the adhesive agent B2.

The adhesive agent B2 may be in contact with the external terminals 60, or it may be in contact with the second insulating substrates 70. That is, the adhesive agent B2 may not only bond the heat radiation plate 40 and the case 50 to each other, but also bond to the heat radiation plate 40 and the case 50, one or both of the leg portions 62 of the external terminals 60 and the second insulating substrates 70.

As described above, in the semiconductor module 10, temperature rise of the external terminals 60 and the bonding wires BW is suppressed.

### 2. Second Embodiment

A second embodiment of the present disclosure is described below. In respective modes exemplified below, elements substantially the same in operations and functions as those described in the first embodiment are denoted by reference signs used in the explanations of the first embodiment and detailed explanations of each are omitted as appropriate.

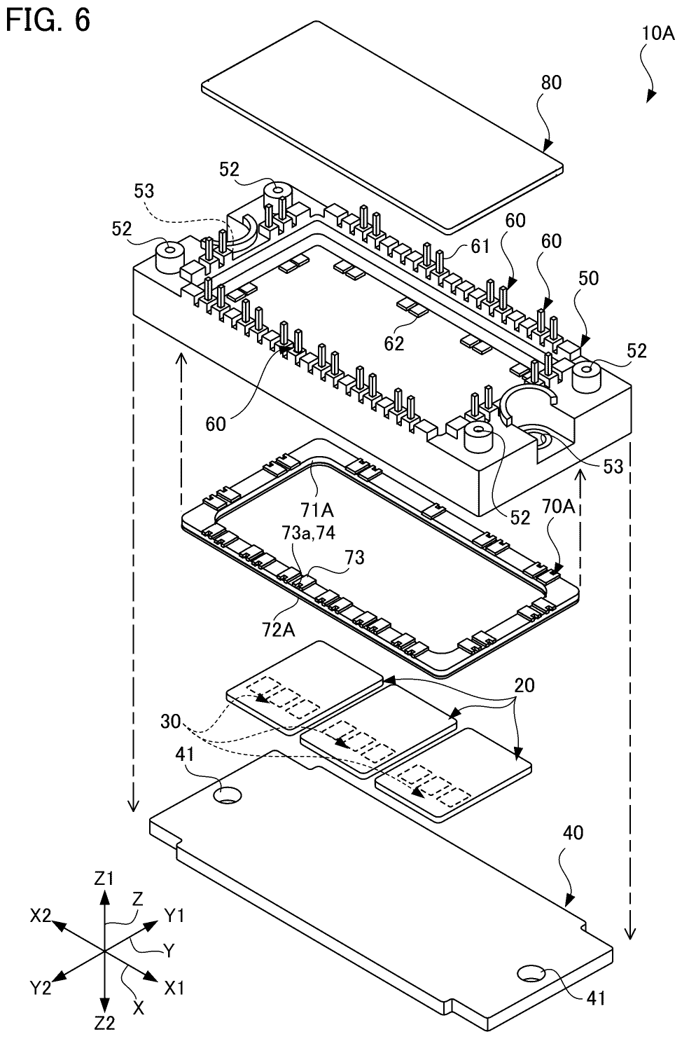

FIG. 6 is an exploded perspective view of a semiconductor module 10A according to the second embodiment. A configuration of the semiconductor module 10A is the same as that of the semiconductor module 10 according to the first embodiment. However, the semiconductor module 10A includes one second insulating substrate 70A in place of the second insulating substrates 70 according to the first embodiment.

A configuration of the second insulating substrate 70A is the same as that of the second insulating substrates 70 according to the first embodiment. However, the second insulating substrate 70A includes one insulating plate 71A and one first conductor 72A in place of the insulating plates 71 and first conductors 72 according to the first embodiment.

A configuration of the insulating plate 71A is the same as that of the insulating plate 71 according to the first embodiment. However, the insulating plate 71A has a frame, the shape of which is along the frame of the case 50. A configuration of the first conductor 72A is the same as the first conductor 72 according to the first embodiment. However, the first conductor 72A is provided throughout the entire region of the insulating plate 71A in a circumferential direction.

In the second embodiment, it is possible to suppress temperature rise of the external terminals 60 and the bonding wires BW. In the present embodiment, second conductors 73 for each of the respective external terminals 60 are arranged on a surface of the insulating plate 71A of one second insulating substrate 70A. As a result, the second insulating substrate 70A can be easily positioned with respect to the heat radiation plate 40. In addition, by increasing the contact area between the heat radiation plate 40 and the second insulating substrate 70A, thermal resistance between the heat radiation plate 40 and the second insulating substrate 70A is reduced.

### 3. Modifications

The present disclosure is not limited to the forementioned embodiments and the following various modifications can be made thereto. The embodiments and modifications may be appropriately combined with one another.

### 3-1. First Modification

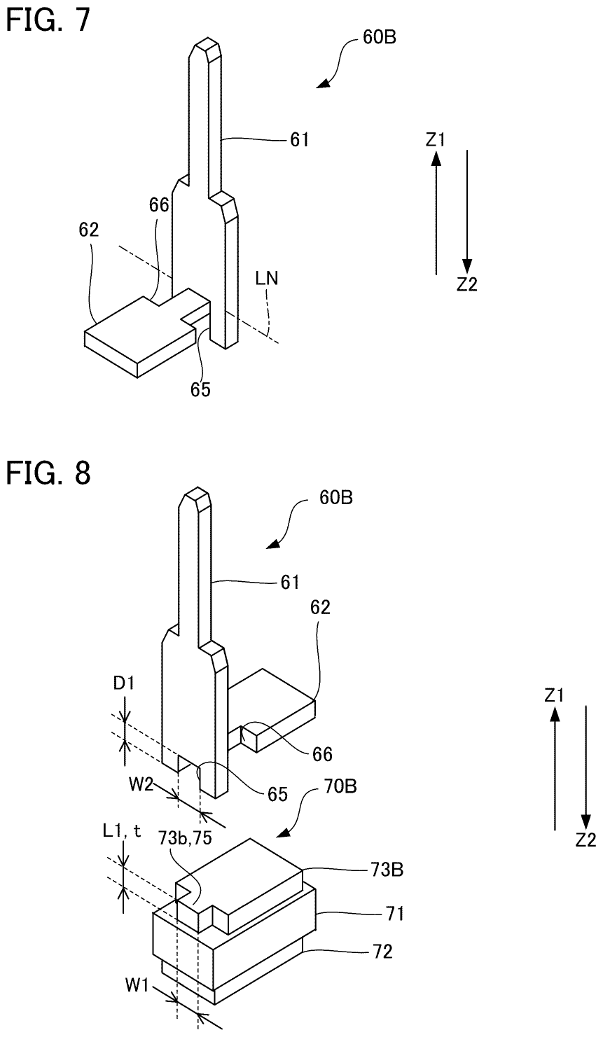

FIG. 7 is a perspective view of an external terminal 60B according to a first modification. FIG. 8 is an explanatory diagram of joining between the external terminal 60B and a second insulating substrate 70B according to the first modification. As illustrated in FIGS. 7 and 8, the external terminal 60B includes the pin portion 61, the leg portion 62, a recess portion 65, and notches 66.

The recess portion 65 of the external terminal 60B is a concave open from the leg portion 62 toward the Z2 direction. The notches 66 are missing portions provided according to formation of the recess portion 65 when the external terminal 60B is formed by a bending process on a metal plate. The shape of the recess portion 65 is not limited to the examples illustrated in FIGS. 7 and 8, and the shape is freely selectable.

The configuration of the second insulating substrate 70B is the same manner as that of the second insulating substrate 70 according to the first embodiment. However, the second insulating substrate 70B includes a second conductor 73B in place of the second conductor 73 according to the first embodiment. The second conductor 73B includes a part 73b. The part 73b constitutes a projection portion 75 to which the recess portion 65 is press-fitted. The shape of the part 73b is not limited to the examples illustrated in FIGS. 7 and 8, and it is freely selectable.

In the first modification, it is possible to suppress temperature rise of the external terminal 60B and the bonding wires BW.

### 3-2. Second Modification

In the forementioned embodiments, layer structures of the second insulating substrates 70, 70A, and 70B are the same as those of the first insulating substrate 20. However, the present disclosure is not limited to these examples, and a second insulating substrate with a layer structure different from that of the first insulating substrate 20 may be used. For example, the thickness of each layer and the number of layers of the second insulating substrate may be different from those of the first insulating substrate 20.

### 3-3. Third Modification

In the first embodiment, the insulating plate 71 is provided for each of the external terminals 60. However, the insulating plate 71 may be configured integrally for each of the external terminals 60. In this case, an insulating plate 71 corresponding to two external terminals 60 and another insulating plate 71 corresponding to one external terminal 60 may be provided in a mixed manner.

### 4. Appendices

For example, the following aspects are derived from the embodiments or the modifications.

### Appendix 1

A semiconductor module according to a first aspect of the present disclosure includes a heat radiation plate, a first insulating substrate disposed on a first surface of the heat radiation plate and having a semiconductor chip provided thereon, a frame-shaped case surrounding the first insulating substrate, a plurality of external terminals provided across inside and outside of the case and electrically connected to the semiconductor chip via a bonding wire, and at least one second insulating substrate disposed between the heat radiation plate and the external terminals and having heat conductivity greater than that of the case. The at least one second insulating substrate and the first surface of the heat radiation plate are bonded to each other by a heat conductive bonding material. Each of the plurality of external terminals and the at least one second insulating substrate are joined to each other by press-fitting.

In this aspect, each external terminal is connected to the heat radiation plate via the second insulating substrate having heat conductivity greater than that of the case, so that Joule heat generated at the bonding wire and the external terminal is released to the heat radiation plate through the second insulating substrate. Since the second insulating substrate and the heat radiation plate are bonded to each other by a bonding material having high heat conductivity, thermal resistance between the second insulating substrate and the heat radiation plate is reduced. In addition, since the external terminal and the second insulating substrate are joined to each other by press-fitting, thermal resistance between the external terminal and the second insulating substrate is reduced, and assembling of the external terminal and the second insulating substrate is facilitated. With this configuration, temperature rise of the external terminal and the bonding wire is suppressed.

### Appendix 2

In a second aspect according to the first aspect, the at least one second insulating substrate comprises a plurality of second insulating substrates. Each of the plurality of second insulating substrates includes an insulating plate, a first conductor disposed on a first surface of the insulating plate and bonded to the first surface of the heat radiation plate by the bonding material, and at least one second conductor disposed on a second surface of the insulating plate and separated for each of the plurality of external terminals.

In this aspect, the second insulating substrate includes the insulating plate, the first conductor, and the second conductor. As a result, the second insulating substrate, a DCB (Direct Copper Bonding) substrate, a DBA (Direct Bonded Aluminum) substrate may be used. The second conductor is separated for each of the external terminals, so that the external terminals can be joined to the second conductor by press-fitting, and conduction between the external terminals is prevented. Since there are two or more second insulating substrates, as compared with an aspect in which there is one second insulating substrates, thermal stress between the second insulating substrates and the case is reduced.

### Appendix 3

In a third aspect according to the second aspect, the plurality of second insulating substrates are separated for each of the plurality of external terminals.

In this aspect, the second insulating substrates can be shared among semiconductor modules different from each other in arrangement of external terminals. As a result, the semiconductor module can be manufactured at a lower cost.

### Appendix 4

In a fourth aspect according to the first aspect, the at least one second insulating substrate is a second insulating substrate. The second insulating substrate includes an insulating plate, a first conductor disposed on a first surface of the insulating plate and bonded to the first surface of the heat radiation plate by the bonding material, and a plurality of second conductors arranged on a second surface of the insulating plate and separated for each of the plurality of external terminals.

In this aspect, since the second insulating substrate includes the insulating plate, the first conductor, and the second conductors, a DCB substrate, a DBA substrate, or the like may be used as the second insulating substrate. Since the plurality of second conductors for the external terminals are arranged on a surface of the insulating plate of the one second insulating substrate, the second insulating substrate can be easily positioned with respect to the heat radiation plate. By increasing the contact area between the heat radiation plate and the second insulating substrate, thermal resistance between the heat radiation plate and the second insulating substrate is reduced.

### Appendix 5

In a fifth aspect according to any of the first to fourth aspects, the case and the heat radiation plate are bonded to each other by an adhesive agent.

In this aspect, insulation between the external terminals and the heat radiation plate is secured, and a gap between the case and the heat radiation plate is sealed by the adhesive agent.

### Appendix 6

In a sixth aspect as a preferred example of any of the first to fifth aspects, the at least one second insulating substrate has the same layer structure as that of the first insulating substrate.

In this aspect, as compared with an aspect in which layer structures of the first insulating substrate and the second insulating substrate are different from each other, the semiconductor module can be manufactured at a lower cost.

### Appendix 7

In a seventh aspect according to any of the first to sixth aspects, each of the plurality of external terminals includes a projection projecting toward the at least one second insulating substrate. The at least one second insulating substrate includes a recess portion configured to fit the projection by press-fitting.

This aspect has an advantage that the contact area between the external terminal and the second insulating substrate is more easily increased as compared with an aspect in which the recess portion provided in the external terminal and the projection portion provided on the second insulating substrate are joined by press-fitting.

### Appendix 8

In an eighth aspect according to the seventh aspect, the recess portion has a hole or a notch opened through the second conductor of the at least one second insulating substrate.

In this aspect, the external terminal and the second insulating substrate can be easily joined to each other by press-fitting.

### Appendix 9

In a ninth aspect as a preferred example of the seventh or eighth aspect, a projecting length of the projection is equal to or less than a thickness of the second conductor of the at least one second insulating substrate.

In this aspect, machining for forming a recess portion in the insulating plate is unnecessary, so that the second insulating substrate is easily manufactured.

### Appendix 10

In a tenth aspect according to any of the first to ninth aspects, each of the plurality of external terminals is formed by a bending process on a metal plate.

In this aspect, the semiconductor module can be manufactured at a lower cost, as compared with a mode in which the external terminals are manufactured by using welding or the like.

### Appendix 11

In an eleventh aspect according to any of the first to tenth aspects, the bonding material is solder.

In this aspect, the heat radiation plate and the second insulating substrate are firmly bonded by the bonding material, and thermal resistance between the heat radiation plate and the second insulating substrate is reduced.

### Appendix 12

In a twelfth aspect according to any of the first to eleventh aspects, the case is formed by insert molding using each of the plurality of external terminals that is an insert part.

In this aspect, the external terminals are firmly and stably fixed to the case, so that the external terminals are joined to the second insulating substrate by press-fitting in a state in which the external terminals are fixed to the case.

### DESCRIPTION OF REFERENCE SIGNS

10 . . . semiconductor module, 10A . . . semiconductor module, 20 . . . first insulating substrate, 21 . . . insulating plate, 22 . . . conductor, 23 . . . conductor, 30 . . . semiconductor chip, 40 . . . heat radiation plate, 41 . . . attachment hole, 50 . . . case, 52 . . . hole, 53 . . . hole, 60 . . . external terminal, 60B . . . external terminal, 61 . . . pin portion, 62 . . . leg portion, 63 . . . projection, 64 . . . hole, 65 . . . recess portion, 66 . . . notch, 70 . . . second insulating substrate, 70A . . . second insulating substrate, 70B . . . second insulating substrate, 71 . . . insulating plate, 71A . . . insulating plate, 72 . . . first conductor, 72A . . . first conductor, 73 . . . second conductor, 73B . . . second conductor, 73a . . . notch, 73b . . . part, 74 . . . recess portion, 75 . . . projection portion, 80 . . . cover, B0 . . . bonding material, B1 . . . bonding material, B2 . . . adhesive agent, B2a . . . part, B2b . . . part, BW . . . bonding wire, D1 . . . depth, LN . . . straight line, PA . . . potting agent, W1 . . . width, W2 . . . width, t . . . thickness.

What is claimed is:

1. A semiconductor module comprising:
a heat radiation plate;
a first insulating substrate disposed on a first surface of the heat radiation plate and having a semiconductor chip provided thereon;
a frame-shaped case surrounding the first insulating substrate;
a plurality of external terminals provided across an inside and an outside of the case and electrically connected to the semiconductor chip via a bonding wire; and
at least one second insulating substrate disposed between the heat radiation plate and the plurality of external terminals and having heat conductivity greater than that of the case,
wherein the at least one second insulating substrate and the first surface of the heat radiation plate are bonded to each other by a heat conductive bonding material, and
wherein each of the plurality of external terminals and the at least one second insulating substrate are joined to each other by press-fitting.

2. The semiconductor module according to claim 1,
wherein the at least one second insulating substrate comprises a plurality of second insulating substrates,
each of the plurality of second insulating substrates includes:
an insulating plate;
a first conductor disposed on a first surface of the insulating plate and bonded to the first surface of the heat radiation plate by the bonding material; and
at least one second conductor disposed on a second surface of the insulating plate and separated for each of the plurality of external terminals.

3. The semiconductor module according to claim 2, wherein the plurality of second insulating substrates are separated for each of the plurality of external terminals.

4. The semiconductor module according to claim 1,
wherein the at least one second insulating substrate is a second insulating substrate,
the second insulating substrate includes:
an insulating plate,
a first conductor disposed on a first surface of the insulating plate and bonded to the first surface of the heat radiation plate by the bonding material, and
a plurality of second conductors arranged on a second surface of the insulating plate and separated for each of the plurality of external terminals.

5. The semiconductor module according to claim 2, wherein the case and the heat radiation plate are bonded to each other by an adhesive agent.

6. The semiconductor module according to claim 2, wherein the at least one second insulating substrate has a same layer structure as that of the first insulating substrate.

7. The semiconductor module according to claim 2,
wherein each of the plurality of external terminals includes a projection projecting toward the at least one second insulating substrate, and
the at least one second insulating substrate includes a recess portion configured to fit the projection by press-fitting.

8. The semiconductor module according to claim 7, wherein the recess portion has a hole or a notch opened through the second conductor of the at least one second insulating substrate.

9. The semiconductor module according to claim 7, wherein a projecting length of the projection is equal to or less than a thickness of the second conductor of the at least one second insulating substrate.

10. The semiconductor module according to claim 7, wherein each of the plurality of external terminals is formed by a bending process on a metal plate.

11. The semiconductor module according to claim 1, wherein the bonding material is solder.

12. The semiconductor module according to claim 1, wherein the case is formed by insert molding using each of the plurality of external terminals that is an insert part.
